(19) United States
(12) Patent Application Publication
(10) Pub. No.: US 2021/0296549 A1
(43) Pub. Date: Sep. 23, 2021

(54) OPTOELECTRONIC SEMICONDUCTOR CHIP AND OPTOELECTRONIC SEMICONDUCTOR COMPONENT

(71) Applicant: OSRAM OLED GMBH, Regensburg (DE)

(72) Inventors: Michael Voelkl, Regensburg (DE); Siegfried Herrmann, Neukirchen (DE)

(21) Appl. No.: 17/264,318

(22) PCT Filed: Jul. 25, 2019
(86) PCT No.: PCT/EP2019/070099

§ 371 Date: Jan. 29, 2021

(30) Foreign Application Priority Data
Jul. 30, 2018 (DE) 10 2018 118 355.0

(51) Int. Cl. H01L 33/62; H01L 33/38; H01L 25/16; H01L 33/46

(52) U.S. Cl. CPC H01L 33/62; H01L 33/46; H01L 25/167; H01L 33/382

(57) ABSTRACT

The optoelectronic semiconductor chip may include a semiconductor layer sequence having an active zone for generating radiation between a first region and a second region. The second region is electrically contacted via electrical through-connections that are electrically connected via metallic contact strips. The first region is electrically contacted via a metallic contact layer. An electrical insulation layer is located between the contact strips and the contact layer. The contact layer and the contact strips are located on a back side of the first region. The through-connections extend from the contact strips through the first region and through the active zone into the second region. The contact strips lie at least predominantly between the back side and the contact layer.

### CROSS-REFERENCE TO RELATED APPLICATIONS

The present application is a national stage entry according to 35 U.S.C. § 371 of PCT application No. PCT/EP2019/070099 filed on Jul. 25, 2019; which claims priority to German Patent Application Serial No. 10 2018 118 355.0 filed on Jul. 30, 2018; all of which are incorporated herein by reference in their entirety and for all purposes.

### TECHNICAL FIELD

An optoelectronic semiconductor chip is specified. Furthermore an optoelectronic semiconductor component is specified.

### BACKGROUND

A task to be solved is to specify an optoelectronic semiconductor chip which can be operated with high currents.

### SUMMARY

The optoelectronic semiconductor chip comprises in a non-limiting embodiment on a semiconductor layer sequence contact strips which contact in particular an n-doped region via through-connections through an active zone. On a side of the contact strips facing away from the semiconductor layer sequence is a planar contact layer as a p-contact arranged. The contact layer extends essentially underneath the entire semiconductor layer sequence, so that the semiconductor chip may be connected to a heat sink via the contact layer. This allows the semiconductor layer sequence to be operated with high current densities for radiation generation.

According to at least one embodiment, the semiconductor chip comprises a semiconductor layer sequence. The semiconductor layer sequence contains an active zone for radiation generation. The active zone is located between a first region and a second region of the semiconductor layer sequence. The first and/or the second region can be formed by one or more semiconductor layers. In a non-limiting embodiment, the first region is p-doped and the second region is n-doped. Alternatively, the two regions may be doped exactly the other way round.

The semiconductor layer sequence is based on a III-V compound semiconductor material. The semiconductor material is for example a nitride compound semiconductor material like AlₙIn₁₋ₙ₋ₘGaₘN or a phosphide compound semiconductor material like AlₙIn₁₋ₙ₋ₘGaₘP or an arsenide compound semiconductor material such as AlₙIn₁₋ₙ₋ₘGaₘAs or such as AlₙGaₘIn₁₋ₙ₋ₘAsₖP₁₋ₖ, where 0≤n≤1, 0≤m≤1 and n+m≤1 and 0≤k<1 respectively. For at least one layer or for all layers of the semiconductor layer sequence 0<n≤0.8, 0.4≤m<1 and n+m≤0.95 as well as 0<k≤0.5. The semiconductor layer sequence may comprise dopants as well as additional components. However, for the sake of simplicity, only the essential constituents of the crystal lattice of the semiconductor layer sequence, i.e. Al, As, Ga, In, N or P, are specified, even if these may be partially replaced and/or supplemented by small amounts of other substances.

In a non-limiting embodiment, the semiconductor layer sequence is based on the material system AlInGaN and is configured to generate blue light.

According to at least one embodiment, the semiconductor chip contains several electrical through-connections. The second region is electrically contacted via the electrical through-connections. The through-connections are metallic.

According to at least one embodiment, the semiconductor chip comprises several metallic contact strips. The through-connections are electrically connected via the contact strips. In a non-limiting embodiment, each of the contact strips is assigned several of the through-connections.

According to at least one embodiment, the semiconductor chip comprises a metallic contact layer. The first region is electrically contacted via the contact layer. The contact layer is composed of several sublayers.

According to at least one embodiment, the semiconductor chip comprises an electrical insulation layer. The insulation layer is located between the contact strips and the contact layer. The insulation layer prevents short circuits between the contact strips and the contact layer.

According to at least one embodiment, the semiconductor layer sequence comprises a back side. The back side is formed by the first region. A light emission side is opposite to the back side. The light emission side is formed by the second region, by a radiolucent substitute carrier or by a growth substrate of the semiconductor layer sequence.

According to at least one embodiment, the contact layer and the contact strips are located on the back side. Especially the light emission side is free of electrical contact structures. In particular, the second region on a side facing away from the back side, especially on the light emission side, is a continuous layer.

According to at least one embodiment, the through-connections extends from the contact strips through the first region and through the active zone into the second region. The contact strips do not penetrate the contact layer. This means that the contact layer may extend continuously over the contact strips.

According to at least one embodiment, the contact strips are mainly or completely arranged between the back side and the contact layer. Predominant means with regard to a length of the contact strips in particular at least 50% or 70% or 85% or 95%.

In at least one embodiment, the optoelectronic semiconductor chip comprises a semiconductor layer sequence, which comprises an active zone for radiation generation between a first region and a second region. The second region is electrically contacted via several electrical through-connections. The through-connections are electrically connected via several metallic contact strips. The first region of the semiconductor layer sequence is electrically contacted via a metallic contact layer. An electrical insulation layer is located between the contact strips and the contact layer. The semiconductor layer sequence comprises a back side, which is formed by the first region. The contact layer and the contact strips are located on the back side. The through-connections extend from the contact strips through the first region and through the active zone into the second region. The contact strips are at least predominantly between the back side and the contact layer.

In particular in headlight and projection applications high luminance density is required. However, conventional LED chips that comprise an internal rewiring structure are limited in terms of their thermal resistance and possible current densities, since in such LED chips, electrical insulation layers are usually applied over the entire surface and form a thermal barrier. Such LED chips can be found, for example, in the publication US 2015/0372203 A1.

In contrast to this, the semiconductor chip described here can be operated with high current densities, since efficient heat dissipation is possible with a simultaneously homogeneous current supply.

In particular, the semiconductor chip described here is a sapphire flip chip, SFC for short, in which the semiconductor layer sequence is located on a sapphire growth substrate. Compared to ordinary SFC's, the present semiconductor chip has been modified. In particular, n-contact bars, i.e. the contact strips, are contacted on the outside below the chip. A p-contact, i.e. the contact layer, is led down almost over the entire surface. A current distribution in the semiconductor component takes place both externally via an n-contact frame of a carrier and internally via the contact strips and through-connections.

The n-contact bars are embedded in an insulation so that they can then be completely covered with a p-metal, for example a silver mirror, an intermediate layer, an adhesion promoting layer and/or an electroplating layer, for example of copper. The electroplated layer can be planarized. To improve the efficiency, a Distributed Bragg Reflector, or DBR for short, in the form of bars, is arranged above the p-contact bars. On a p-face of the semiconductor body, i.e. on the back side, a metal mirror and a DBR are alternately and linearly arranged. The DBR can be underlaid with a layer of a transparent conductive material such as ITO.

Thus, the semiconductor chip described here can achieve a high luminance density with efficient heat dissipation. Heat is dissipated completely or almost completely over the metallic chip socket. This is possible in particular because only partial line-shaped insulation layers are present, in contrast to semiconductor chips which comprise an internal rewiring level with a full-surface insulation layer, as described in US 2015/0372203 A1.

Since in the semiconductor component specified here a current distribution can be made by n-junctions on a carrier outside the semiconductor chip, the current can be injected much more homogeneously into the semiconductor chip. In conventional semiconductor chips with a rewiring level, the current distribution is limited by the thickness of the metal layer on the entire surface of the chip in the level of the chip where the through-connections in the chip are electrically connected.

Furthermore, certain chip regions can optionally be supplied with a higher current. This makes it possible to use the effect that a volume emitter with a translucent growth substrate shows a higher radiation decoupling efficiency at one chip edge than in the center of the chip. Therefore, the current density at the chip edge can be increased with respect to the center in order to exploit this effect and to achieve a higher outcoupling efficiency. In addition, it is possible to configure regions with higher current density below an emission aperture than at an edge. This allows a higher luminance to be achieved below an emission aperture and a higher proportion of directly coupled out radiation.

The semiconductor chip described here is a flip-chip and can be installed as a flip-chip. Conventional flip-chips can be replaced by the semiconductor chip described here.

The semiconductor chip and the semiconductor component described here are applicable for example in headlights and projection applications. Furthermore, an installation in a housing with a white frame, especially formed by a potting with reflecting particles, is possible. Various conversion technologies for wavelength conversion can be combined with the semiconductor chip and the semiconductor component described here. The semiconductor component can be based on a package, which is based on a ceramic or on a lead frame construction. A mounting on metal core boards or printed circuit boards is possible. Reflectors can be used, in which the semiconductor chip and/or the semiconductor component are built in.

According to at least one embodiment, the semiconductor chip comprises one or more strip mirrors. The at least one strip mirror is located between the first region and the contact strips. It is possible that the strip mirror is essentially limited to the contact strips or is congruent with the contact strips. Essentially limited to the contact strips can mean that the strip mirror laterally projects beyond the contact strips by a maximum of 10% or 20% or 40% of one width of the contact strips and/or by a maximum of 5 μm or 10 μm or 30 μm.

According to at least one embodiment, the strip mirror is electrically insulating. In particular, the strip mirror is formed by a Bragg mirror, or DBR for short. The Bragg mirror comprises layers with alternating high and low refractive indices. To achieve high thermal conductivity through the strip mirror, the strip mirror comprises a maximum of 20 or ten or five or four pairs of layers. The layer pairs are formed, for example, from silicon dioxide and titanium dioxide. Alternatively or additionally, there are at least three or five or eight pairs of layers with one high refractive and one low refractive layer. The Bragg mirror can be provided with a reflective metal layer, for example of silver or aluminum, on a back side. Such a metal layer can be electrically isolated from other components of the semiconductor chip or electrically connected to the contact layer. For the through-connections, the Bragg mirror comprises recesses or breakthroughs. An electrically conductive material of the through-connections can directly border the materials of the layer pairs, but is electrically separated from the optional metal layer on the Bragg mirror.

According to at least one embodiment, the contact layer extends in a central region of the semiconductor chip without gaps and continuously over all contact strips. The central region makes up at least 60% or 80% or 90% or the entire base surface of the semiconductor layer sequence. The central region is surrounded by an edge region all around or at least in strips on one or more sides when viewed from above.

According to at least one embodiment, the contact layer in the central region forms a first electrical contact surface. The first electrical contact surface forms an external electrical connection of the semiconductor chip for the first region of the semiconductor layer sequence. In the region of the contact surface it is possible that the contact layer comprises a contact metallization or is provided with a contact metallization. Via such a contact metallization, the contact surface can be contacted by soldering, for example.

According to at least one embodiment, the contact strips are completely enclosed by the strip mirror together with the insulation layer in regions between adjacent through-connections as seen in cross-section. This means that the contact strips between adjacent through-connections in this case are only bordered by the strip mirror and the insulation layer. The strip mirror separates the contact strips from the first region of the semiconductor layer sequence and the insulation layer forms a separation from the contact layer.

According to at least one embodiment, the contact strips are only free of the contact layer in an edge region of the semiconductor chip when viewed in plan view. This means that at least one second electrical contact surface can be formed in the edge region of the contact strips. The at least one second contact surface is configured for external electrical contact of the semiconductor chip for the second region of the semiconductor layer sequence. In a non-limiting embodiment, the second contact surfaces are electrically and mechanically connectable by soldering.

According to at least one embodiment, the contact strips are electrically controllable independently of one another, individually or in groups. In a non-limiting embodiment at least one second contact surface for each contact strip or group is thus present. For example, there is exactly one or exactly two second contact surfaces per contact strip or per group.

According to at least one embodiment, the contact strips are electrically short-circuited with each other. In particular, only one second contact surface or two second contact surfaces are provided for all contact strips together.

According to at least one embodiment the second contact surfaces are completely covered by the second region of the semiconductor layer sequence. This means that the second contact surfaces do not project beyond the semiconductor layer sequence laterally.

Alternatively, the second contact surfaces partly or completely protrude laterally over the semiconductor layer sequence. That means, seen in top view, the second contact surfaces can be completely or partially next to the semiconductor layer sequence.

According to at least one embodiment, the contact layer comprises an adhesion promoting layer, a metallic mirror layer, a diffusion barrier layer and/or a metallic support layer. These layers follow each other in the indicated order in the direction away from the semiconductor layer sequence, in particular directly one after the other. For example, the adhesion promoting layer is a titanium layer with a thickness of 1 nm at most. The mirror layer is in particular a silver layer, an aluminum layer or a gold layer. A thickness of the mirror layer is at least 30 nm and/or at most 300 nm. For example, the diffusion barrier layer is made of Ti, Pt, TiW and/or TiWN with a thickness of at least 5 nm and/or at most 200 nm. The metallic support layer is made of copper and can be produced by electroplating. A thickness of the support layer is at least 3 μm and/or at most 30 μm.

According to at least one embodiment, the adhesion promoting layer, the diffusion barrier layer and/or the mirror layer is located directly on the insulation layer. This means that the adhesion promoting layer, the diffusion barrier layer and/or the mirror layer can reproduce the contact strips, and thus the insulation layer, true to shape.

According to at least one embodiment, the contact strips are thick. For example, the contact strips comprise a thickness of at least 2 μm or 5 μm and/or of at most 30 μm or 15 μm. In contrast, the insulation layer is thin, for example with a thickness of at least 10 nm and/or of at most 250 nm. The contact strips may be composed of several metals, for example a thin silver layer, a thin diffusion barrier layer and a thick copper layer, similar to the contact layer. The insulation layer is made of an oxide like silicon dioxide.

According to at least one embodiment, a cross-sectional area of the contact strips and/or an areal density of the through-connections decreases in the direction towards a chip center. Thus, lower current densities may be achieved in the chip center. Alternatively, for a higher current density in the chip center, an areal density of the through-connections may increase towards the center of the chip. Instead of the areal density of the through-connections, the current conducting cross-section may be adjusted.

According to at least one embodiment, the area percentage of the contact strips and also of the strip mirror is at least 5% or 10% and/or at most 25% or 20% of a base area of the semiconductor layer sequence. Alternatively or additionally, an area percentage of the through-connections on the back side of the semiconductor layer sequence is at least 0.5% or 1% and/or at most 8% or 5% or 3%. This means that the contact strips make up a significantly larger area on the back side than the through-connections.

According to at least one embodiment, the semiconductor chip comprises a growth substrate for the semiconductor layer sequence, especially made of sapphire. The growth substrate is located at the second region. In a non-limiting embodiment, the growth substrate is the component of the semiconductor chip that mechanically carries and supports it.

Furthermore, an optoelectronic semiconductor component is specified. The semiconductor component comprises at least one semiconductor chip as specified in connection with one or more of the above mentioned embodiments. Features of the semiconductor component are therefore also disclosed for the semiconductor chip and vice versa.

In at least one embodiment, the semiconductor component comprises one or more semiconductor chips on a front side. Furthermore, the semiconductor component comprises a carrier. The carrier comprises a first electrical connection for the first region and one or more second electrical connections for the second region. The first connection extends through the carrier, as it can also apply to the second connection. A base surface of the first connection is continuously at least 70% or 90% of a base surface of the first contact surface of the semiconductor chip. In a non-limiting embodiment, the base surface of the first connection is at least as large as the base surface of the contact surface to ensure efficient heat dissipation of the semiconductor chip through the carrier.

According to at least one embodiment, the second connection is structured on the front side into several webs in the form of strips or grids. Thus, it is possible that the second connection takes up only a comparatively small area of the front side.

According to at least one embodiment, the first and the second connection on an mounting side opposite the front side are each formed by a continuous surface. For example, the connections on the mounting side are rectangular or approximately rectangular, for example with rounded corners.

According to at least one embodiment, regions between the webs are filled with a reflective coating. Such a coating is formed, for example, by a silicone or by another plastic in which reflecting particles, for example of titanium dioxide, are embedded. In this way, reflection losses on metallic structures can be reduced.

According to at least one embodiment, the carrier protrudes laterally beyond the semiconductor chip all around. Alternatively, it is possible that the carrier and the semiconductor chip are flush with each other and/or congruent.

According to at least one embodiment, the second connection frames the semiconductor chip at the front side predominantly or completely as seen in plan view. Predominant means in particular at least 70% or 85% or 95%.

According to at least one embodiment, the semiconductor component is configured to operate the active zone with a current density of at least 2 A/mm² or 4 A/mm² or 6 A/mm². This means that the electrical leads, especially the conductor cross-sections of the through-connections and contact strips, are designed accordingly.

According to at least one embodiment, the active zone and/or the semiconductor layer sequence comprises a base surface of at least 0.5 mm² or 0.9 mm². Alternatively or additionally the size of the base surface is at most 10 mm² or 5 mm² or 2 mm².

In the following, an optoelectronic semiconductor chip described here and an optoelectronic semiconductor component described here are explained in more detail with reference to the drawings using exemplary embodiments. Identical reference signs specify identical elements in the individual figures. However, no true-to-scale references are shown. For better understanding, individual elements may be shown in excessive size.

### BRIEF DESCRIPTION OF THE DRAWINGS

The accompanying drawings serve to provide an understanding of non-limiting embodiments. The drawings illustrate non-limiting embodiments and, with the description, serve to explain them. Further non-limiting embodiments and numerous intended advantages emerge directly from the following detailed description. The elements and structures shown in the drawings are not necessarily shown true to scale. Identical reference numerals refer to identical or corresponding elements and structures.

In the figures:

FIGS. 1 to 5 show schematic sectional views of exemplary embodiments of optoelectronic semiconductor chips described here,

FIG. 6 shows a perspective top view of an exemplary embodiment of an optoelectronic semiconductor chip described here,

FIG. 7 a perspective bottom view of an exemplary embodiment of an optoelectronic semiconductor chip described here,

FIG. 8 a schematic bottom view of an exemplary embodiment of an optoelectronic semiconductor chip described here,

FIG. 9 a schematic side view of an exemplary embodiment of an optoelectronic semiconductor chip described here,

FIGS. 10 to 13 schematic bottom views of exemplary embodiments of optoelectronic semiconductor chips described here,

FIGS. 14 and 15 schematic perspective views of the electrical contacting of exemplary embodiments of optoelectronic semiconductor chips described here,

FIGS. 16 to 18 schematic bottom views of contact strips for exemplary embodiments of optoelectronic semiconductor chips described here,

FIG. 19 a schematic sectional view of an exemplary embodiment of an optoelectronic semiconductor component described here,

FIGS. 20 and 21 schematic perspective views of exemplary embodiments of optoelectronic semiconductor components described here,

FIG. 22 a schematic perspective view of an electrical contact structure of an exemplary embodiment of an optoelectronic semiconductor component described here,

FIG. 23 shows a schematic perspective view of an exemplary embodiment of an optoelectronic semiconductor chip described here,

FIGS. 24 to 27 schematic sectional views of exemplary embodiments of optoelectronic semiconductor components described here, and

FIGS. 28 to 33 schematic perspective views of exemplary embodiments of optoelectronic semiconductor components described here.

### DETAILED DESCRIPTION

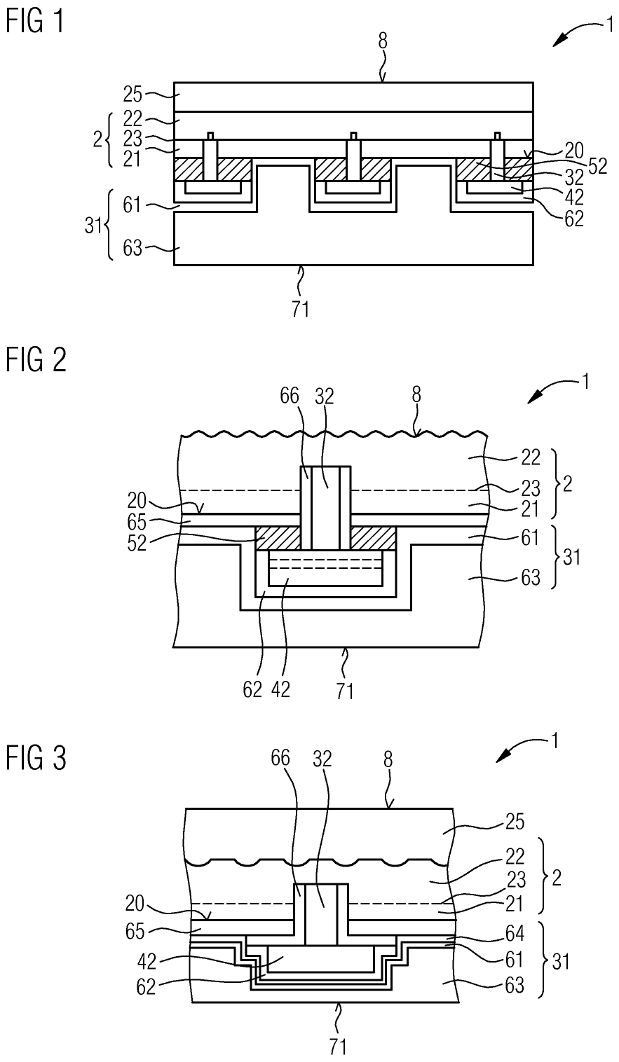

FIG. 1 shows an exemplary embodiment of an optoelectronic semiconductor chip 1. On a growth substrate 25, for example made of sapphire, there is a semiconductor layer sequence 2. The growth substrate 25 represents a light emission side 8 of the semiconductor chip 1. The semiconductor layer sequence 2 comprises a first region 21 and a second region 22, between which an active zone 23 is located. The first region 21 is p-doped and the second region 22 is n-doped. The semiconductor layer sequence 2 is especially based on the material system AlInGaN.

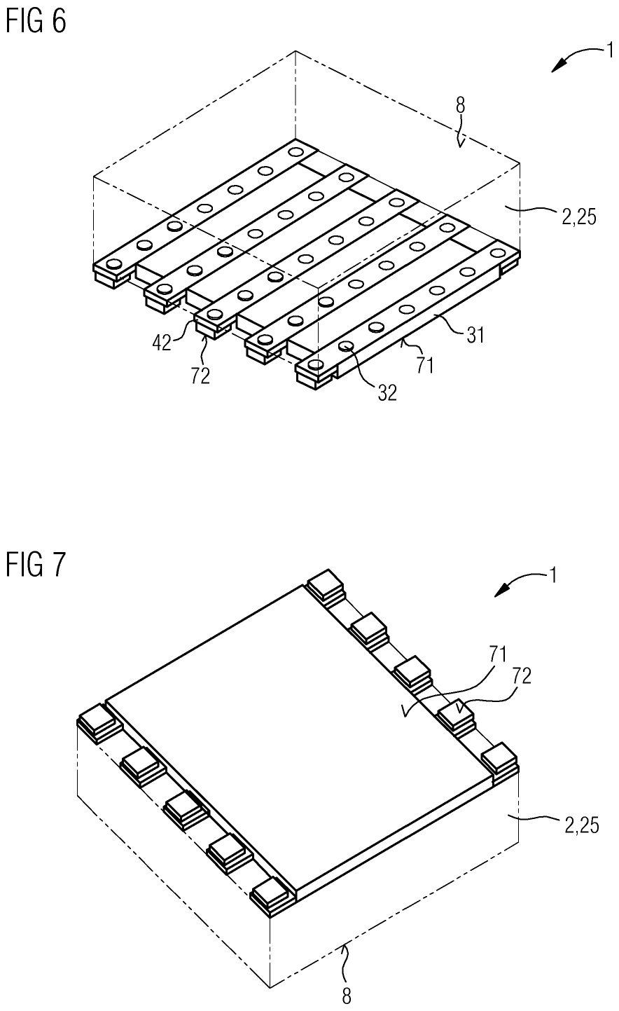

For the electrical contacting of the second region 22 several electrical through-connections 32 are provided. From a back side 20 of the semiconductor layer sequence 2, which is formed by the first region 21, the through-connections 32 extend through the active zone 23 and end in the second region 22. The individual through-connections 32 are connected by electrical contact strips 42. The contact strips 42 run perpendicular to the drawing plane in FIG. 1, see also FIG. 6.

In FIG. 1 only two of the through-connections 32 are drawn. In a non-limiting embodiment, at least 4×4 or 6×6 and/or at most 50×50 or 12×12 of the through-connections 32 are present when viewed from above. The through-connections 32 can be arranged in a regular pattern when viewed from above, in particular in the form of a matrix.

To avoid electrical short circuits, a strip mirror 52 is located between the contact strips 42 and the first region 21. The strip mirror 52 is a Bragg mirror, or DBR for short. On a side facing away from the back side 20, the contact strips 42 are completely covered by an electrical insulation layer 62, which extends to the strip mirror 52.

An average diameter of the through-connections 32, for example, is at least 3 μm and/or at most 50 μm. The contact strips 42 are wider than the through-connections 32 when viewed in cross-section perpendicular to the back side 20 and to the contact strips 42. For example, a width of the contact strips 42 is at least 10 μm or 20 μm larger than the average diameter of the through-connections 32.

Furthermore, the semiconductor chip 1 comprises a contact layer 31. The contact layer 31 electrically connects the first region 21. The contact layer 31 is composed of several sub-layers 61, 63.

A metallic mirror layer 61 of the contact layer 31 is comparatively thin and extends over the back side 20 and thus over the contact strips 42 including the associated components. The mirror layer 61 is made of silver with a thickness around 100 nm. The mirror layer 61 reproduces the shape of the contact strips 42.

The mirror layer 61 is completely covered by a support layer 63. The support layer 63 is comparatively thick and made of copper, for example. In contrast to the illustration in FIG. 1, it is possible, as in all other exemplary embodiments, that there is an undrawn diffusion barrier layer between the layers 61, 63, for example of titanium or titanium tungsten nitride.

One side of the contact layer 31 facing away from the back side 20 may be planar and forms a first electrical contact surface 71. Thus, the support layer 63 and the first contact surface 71 essentially extend over the entire semiconductor layer sequence 2. Thus, efficient heat dissipation from the semiconductor layer sequence 2 is possible. This is particularly due to the fact that the strip mirror 52 and the insulation layer 62 cover only a comparatively small area of the back side 20. Thus, only a comparatively low thermal resistance can be realized towards the first contact surface 71.

The exemplary embodiment of FIG. 2 shows that the through-connections 32 are laterally surrounded by an electrical insulation 66 to prevent short circuits in the region of the through-connections 32. Furthermore it is illustrated that the growth substrate can be removed. Thus the light emission side 8 can be formed by the second region 22. The light emission side 8 is optionally provided with a roughening.

Furthermore, it is illustrated in FIG. 2 that a transparent conductive layer 65 is present. The layer 65 is made of a transparent conductive oxide, TCO for short, like ITO. The layer 65 can extend to the insulation 66 and thus extend below the strip mirror 52. This means that the first region 21 may be supplied with current over essentially the entire surface. The layer 65, for example, is at least 30 nm and/or at most 200 nm thick.

In addition, FIG. 2 shows that the contact strips 42 may have a multilayer structure. For example, a partial layer closest to the back side 20 is formed as a mirror like a silver mirror. The partial layer of the contact strips 42 lying further from the back side 20 is thermally conductive and made of copper, for example. Again, there may be an undrawn, thin, central diffusion barrier layer present.

In all other respects, the statements in context of FIG. 1 apply accordingly to FIG. 2.

According to FIG. 3, the growth substrate 25 is a sapphire substrate. The growth substrate 25 can contain structures and thus be a structured sapphire substrate, also called Pattern Sapphire Substrate or PSS for short.

With regard to the contact layer 31, it is shown that an adhesion promoting layer 64, for example of platinum or titanium, can be present in direction towards the semiconductor layer sequence 2. The adhesion promoting layer 64 is very thin and optically not or not significantly effective. In particular, if the adhesion promoting layer 64 is present, the transparent conductive layer 65 can also be omitted. If the layer 65 is present, the layer 65 itself can serve as the adhesion promotion layer, so that the layer 64 can be omitted.

Furthermore, FIG. 3 illustrates that the insulation 66 is L-shaped on both sides of the through-connection 32. This means that the insulation layer 62 may also extend onto the insulation 66 and may partially run parallel to it. Thus, it is possible that the contact strips 42 are enclosed by the insulation 66 and by the insulation layer 62 seen in cross section, at least in region between adjacent through-connections 32.

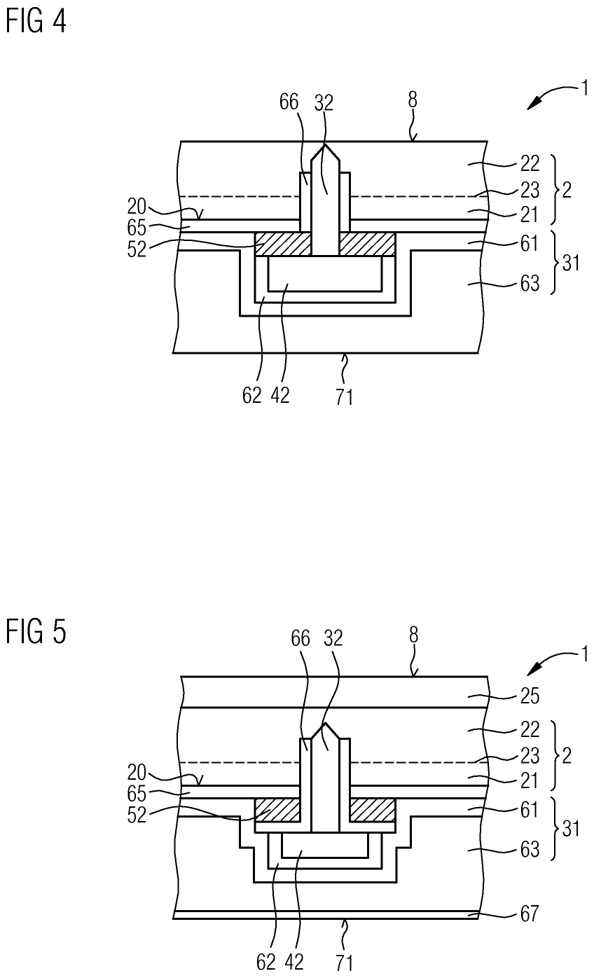

FIG. 4 shows that the strip mirror 52 and the contact strip 42 are laterally flush with each other. The insulation layer 62 can extend to the transparent conductive layer 65. The insulation 66 may terminate flush with the back side 20.

As in all other exemplary embodiments, it is possible that a tip of the through-connections 32 are each not planar, but rather frustoconical or frustopyramidal or cylindrical with a smaller diameter. This allows an electrical contact surface to be enlarged towards the second region 22.

According to FIG. 5, the insulation 66 extends to the strip mirror 52. The insulation layer 62 extends to the insulation 66 or, in deviation from the illustration in FIG. 5, also to the strip mirror 52. This allows the metallic mirror layer 61 to run in multiple steps in the region of the contact strips 42 and to border directly on the insulation 66 in certain sections.

Optionally, the contact layer 31 may be provided with a contact metallization 67, which is formed with one or more metal layers, for example gold, tin and/or nickel. The contact metallization 67 allows soldering of the semiconductor chip 1. Such contact metallization 67 can also be present in all other exemplary embodiments for electrical contact surfaces.

FIG. 6 shows that there are several square or rectangular second contact surfaces 72 for the electrical connection of the contact strips 42 at one edge of the semiconductor chip 1. In all other respects, the explanations given in context of FIGS. 1 to 5 apply accordingly.

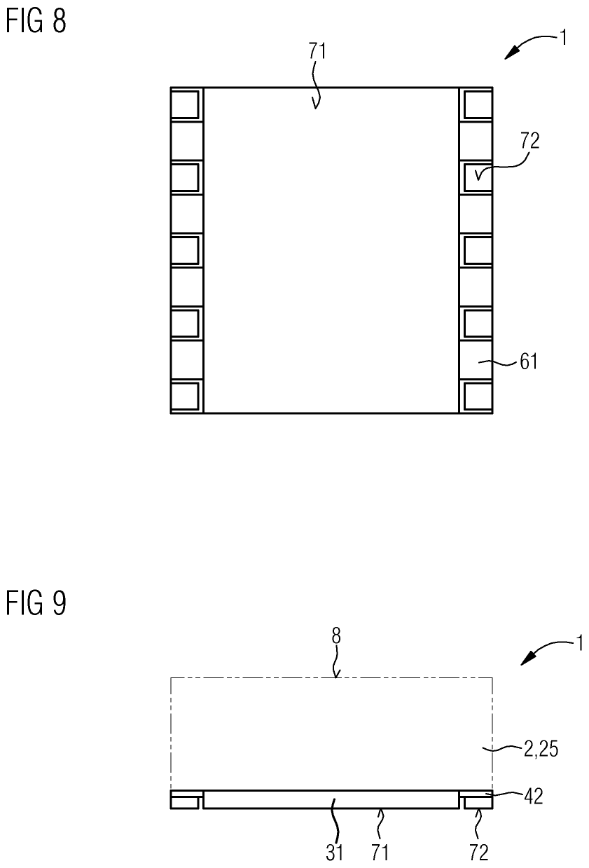

FIG. 7 shows a bottom view of the second electrical contact surfaces 72. The second contact surfaces 72 extend on both sides and symmetrically along the first contact surface 71, see also FIG. 8. A corresponding side view is shown in FIG. 9.

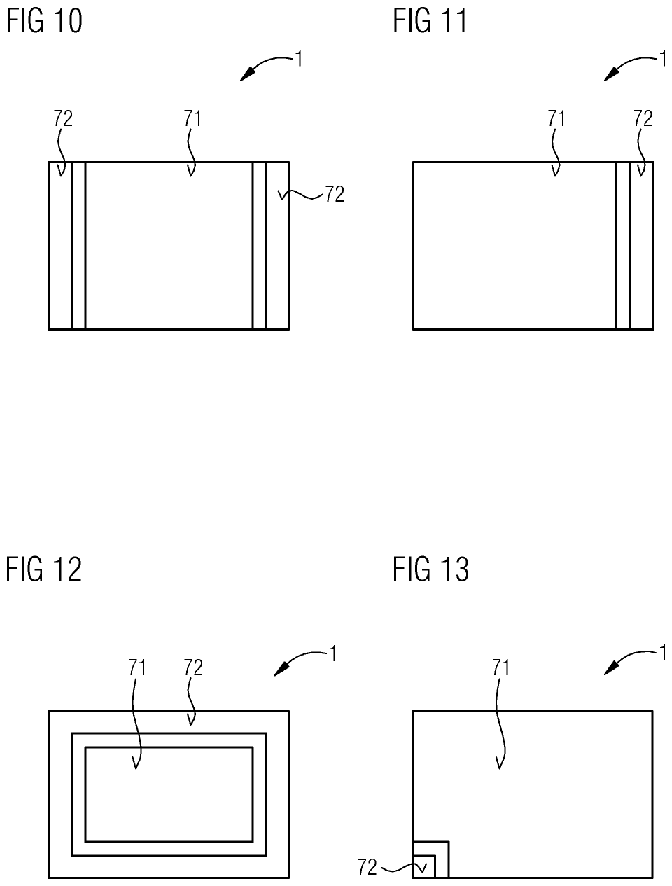

FIGS. 10 to 13 show further bottom views. The second contact surfaces 72 may be strip-shaped, see FIG. 10. It is possible that there is only one strip for the second contact surface 72, see FIG. 11. According to FIG. 12, the second contact surface 72 surrounds the first contact surface 71 in a frame shape. In FIG. 13, the second contact surface 72 is located in only one corner region of the semiconductor chip 1. Other regions are covered by the contact surface 71, which comprises a cutout for the second contact surface 72.

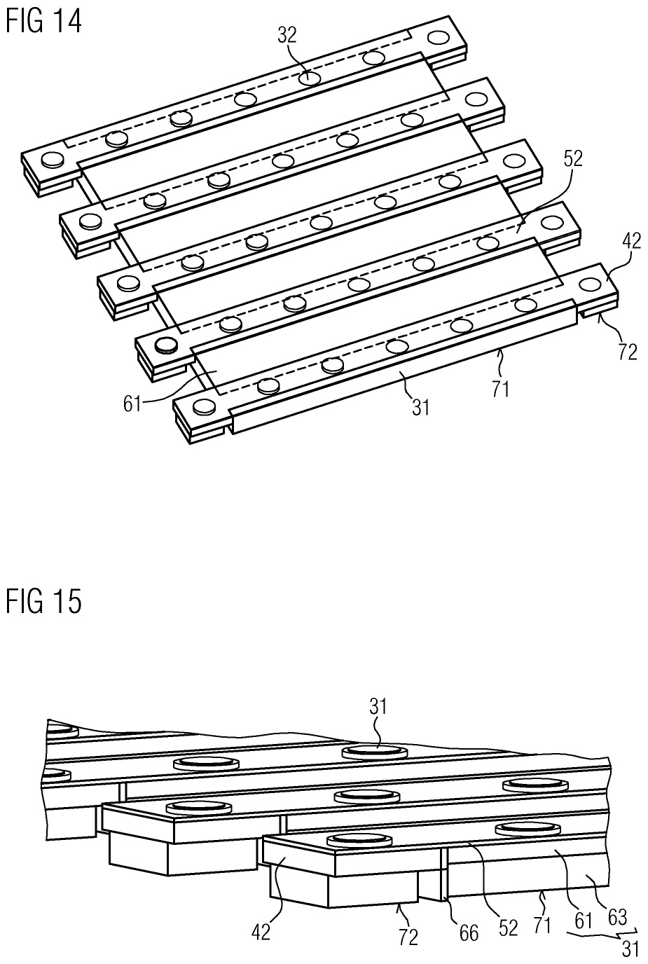

FIGS. 14 and 15 illustrate the contact structure of semiconductor chip 1. For better visibility, the semiconductor layer sequence and the growth substrate are not drawn.

It can be seen that the contact strips 42 at the edge of the semiconductor chip extend beyond the contact layer 31. In the direction away from the undrawn semiconductor layer sequence, the second contact surfaces 72 are present. The second contact surfaces 72 may be constructed in the same way as the first contact surfaces 71 and accordingly have several layers. Between the second contact surface 72 to the first contact surface 71, an insulation 66 is present. As an alternative to insulation 66, an air gap may also be formed.

The contact strips 42 are not electrically connected directly to each other within the semiconductor chip 2. Therefore, the contact strips 42 can be electrically controlled individually.

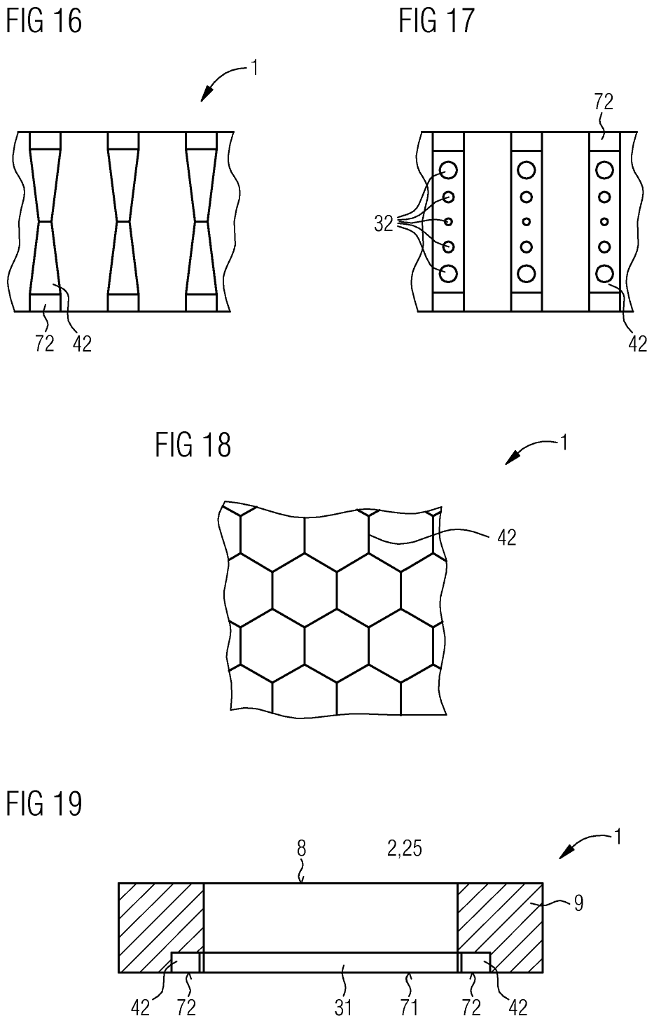

FIGS. 16 to 18 show design possibilities of the contact strips 42, which can be implemented in the exemplary embodiments of FIGS. 1 to 15.

As shown in FIG. 16, the contact strips 42 become narrower towards the center of the semiconductor chip 1, thus increasing the electrical resistance of the contact strips 42 towards the center of the semiconductor chip 1. As a result, the semiconductor chip is less energized in a center. Since light is mainly extracted via side surfaces, a higher light extraction efficiency can be achieved.

In FIG. 17 the contact strips 42 comprise a constant width. However, a diameter of the through-connections 32 increases towards a center of the semiconductor chip 1. Thus the same effect as in FIG. 16 can be achieved. Alternatively, in contrast to the illustrations in FIGS. 16 and 17, an areal density of the through-connections 32 can also be varied in order to locally adjust the current density.

FIG. 18 illustrates that the contact strips 42 can be grid-shaped, e.g. in the form of a hexagonal grid or, deviating from the illustration in FIG. 18, also in the form of a square or rectangular grid. The contact strips 42 are thus electrically short-circuited within the semiconductor chip 2.

In the semiconductor chip 1 of FIG. 19, the second contact surfaces 72 are located on the side next to the semiconductor layer sequence 2. Mechanical stabilization of the contact surfaces 72 is achieved, for example, by means of a potting 9, which can be reflective. Such a potting 9 can also be present in all other exemplary embodiments.

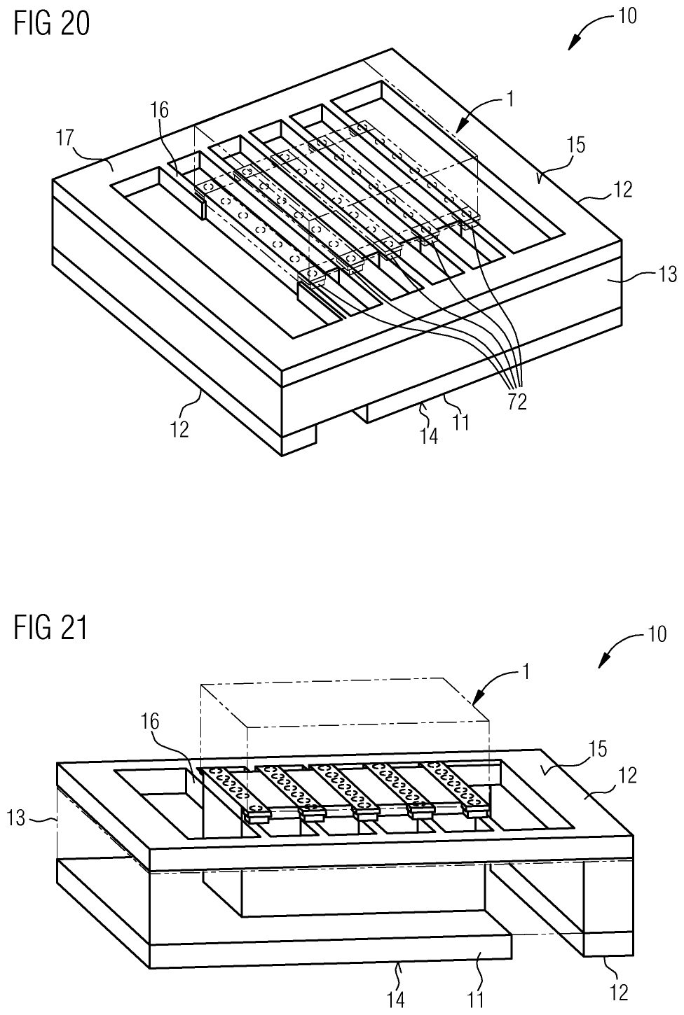

FIG. 20 shows an exemplary embodiment of an optoelectronic semiconductor component 10. The semiconductor chip 1 is located in the center of a carrier 13. The contact surfaces of the semiconductor chip 1 are attached to electrical connections 11, 12. A second connection 12 for the second region of the semiconductor layer sequence comprises several webs 16, each of which leads to the second contact surfaces.

The second connection 12 surrounds the semiconductor chip 1 all around at a front side 15 of the carrier 13 when viewed from above, in order to achieve an even current distribution. A mounting side 14, which is opposite the front side 15, is configured for solder mounting of the semiconductor component 10.

There can also be several second connections 12 for each of the individual contact strips 42 in order to control the contact strips 42 electrically independently of each other. In a non-limiting embodiment, however, the semiconductor component 10 comprises only one first and only one second connection 11, 12 on the mounting side 14.

Optionally, a reflective coating 17 is provided between the webs 16. Absorption losses at the carrier 13 can be reduced by the reflective coating 17, in particular since a smaller areal fraction of the front side 15 is covered by the webs 16. Furthermore, the design of the second connection 12 on the front side 15 with the webs 16 makes it possible to absorb thermal distortions, so that the semiconductor chip 1 is exposed to lower mechanical stress.

In FIG. 21, the carrier 13 is shown transparently for better illustration. It can be seen that the connections 11, 12 run through the carrier from the mounting side 14 to the front side 15. The first connection 11 comprises a cross-sectional area from the mounting side 14 to the front side 15 which corresponds to at least one area of the first contact surface of the semiconductor chip 1. This enables efficient heat dissipation of the semiconductor chip 1 through the carrier 13. In a plan view, the first contact surface of the semiconductor chip 1 and a region of the first region of the first connection 11 running in the carrier 13 can be congruent. In all other respects, the explanations with respect to FIG. 20 apply accordingly.

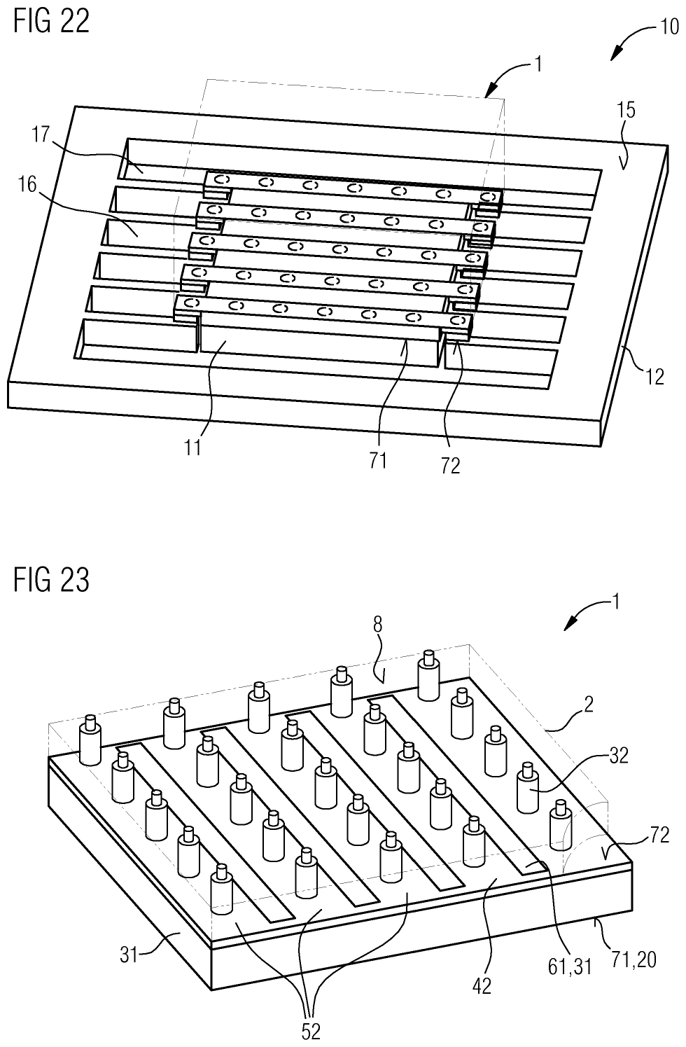

The contact structure of the semiconductor component 10 of FIG. 21 is illustrated again in FIG. 22. In particular, it can be seen that the first connection 11 on the front side 15 is congruent with the first contact surface 71. The carrier 13 is not illustrated to simplify the illustration.

In the exemplary embodiment shown in FIG. 23, at least one second contact surface 72 faces the light emission side 8. The second contact surface 72, for example, is restricted to a corner area. The second contact surface 72 is configured for example for a bonding wire contact. Thus, the first contact surface 71 may form the entire or essentially the entire back side 20 of the semiconductor chip 1. Deviating from the illustration in FIG. 23, several second contact surfaces 72 may be present. The contact strips 42, for example, are electrically connected at an edge of the semiconductor chip 1 to the at least one associated second contact surface 72.

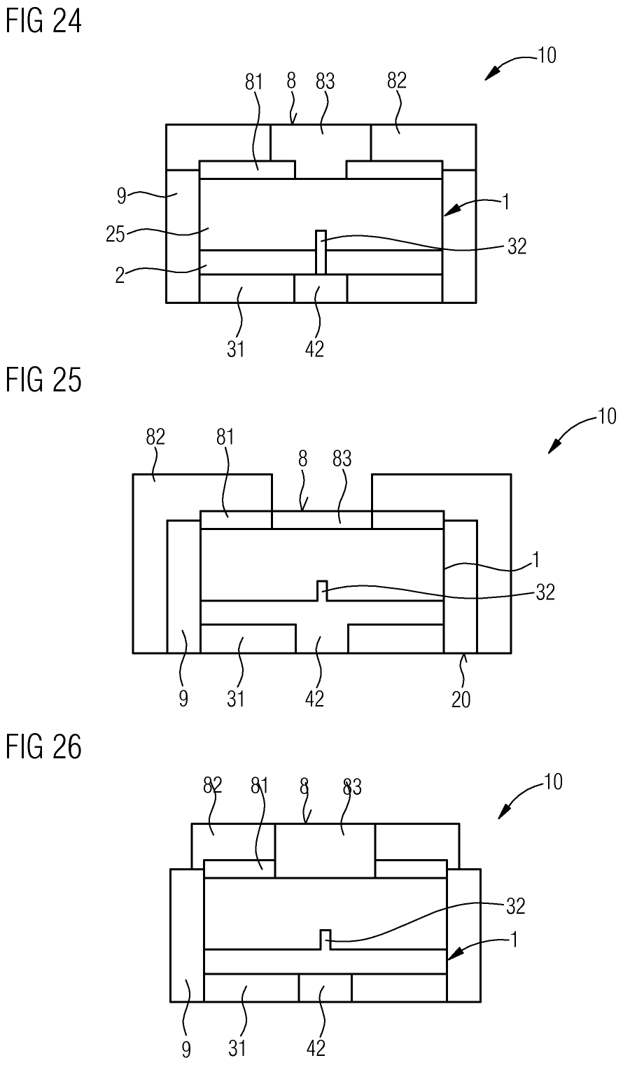

FIGS. 24 to 27 each refer to further exemplary embodiments of the semiconductor components 10. The electrical contacting is only indicated in each case and is designed, as explained in connection with FIGS. 1 to 23.

The semiconductor components 10 each include the potting 9, which appears white and reflects diffusely. On a side facing the light emission side 8, the growth substrate 25 or optionally the semiconductor layer sequence 2 itself is provided with an additional mirror 81, for example a Bragg mirror or a metal mirror. The additional mirror 81 comprises a strip-shaped opening which can be provided with a phosphor 83. This slit or stripe in the additional mirror 81 may increase the luminance density because the light generated only emerges from the semiconductor chip 1 in a relatively small area. For example, the stripe covers at least 10% or 20% and/or at most 40% or 25% of the semiconductor layer sequence 2.

On the potting 9 and/or on the additional mirror 81 there is an optional optical aperture 82, which is opaque. The aperture 82 is, for example, a metal layer or an especially white potting body. Side surfaces of the phosphor 83 can be completely covered by the aperture 82. A thickness of aperture 82, for example, is at least 10 μm and/or at most 50 μm. In contrast to FIG. 24, the phosphor 80 may also protrude beyond the 82 aperture.

As shown in FIG. 25, aperture 82 also extends on the side surfaces of potting 9 and can extend to back side 20. The additional mirror 81 and the aperture 82 may be flush with each other, unlike in FIG. 24, where the aperture 82 is set back in relation to the additional mirror 81.

FIG. 26 shows that the aperture 82 can also only partially cover the potting 9.

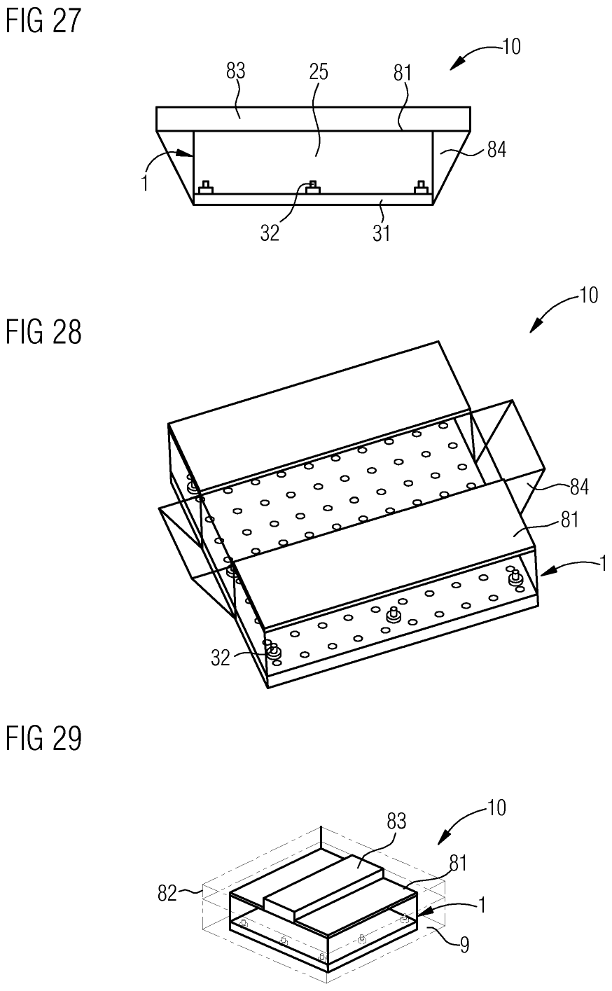

The sectional view in FIG. 27 is rotated by 90° in relation to FIGS. 24 to 26 in relation to a top view. This means that the cut is longitudinal to the stripe formed by the phosphor 83 as shown in FIG. 27. Optionally, a clear potting 84 is arranged at the ends of the stripe of phosphor 83 on the semiconductor chip 1. The clear potting 84 may widen in a wedge shape towards the phosphor 83. Thus, the non-drawn potting 9, which is located on the outside of the clear potting 84, can act as a reflective surface towards the phosphor 83.

The semiconductor component 10 of FIG. 27 is again shown in perspective in FIG. 28, but without the potting 9, the phosphor 83 and the optional aperture 82.

FIG. 29 shows the semiconductor component 10 of FIG. 24 again, whereby the potting 9 and the aperture 82 may also be formed as one piece.

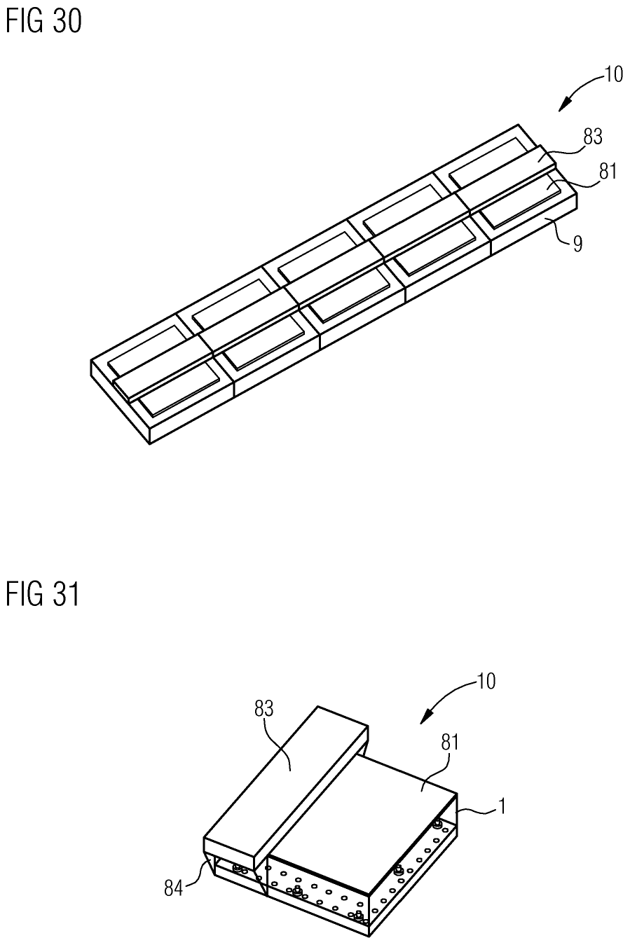

FIG. 30 illustrates that several of the units shown in FIGS. 24 to 29 can be left in series and concluded into a single semiconductor component 10.

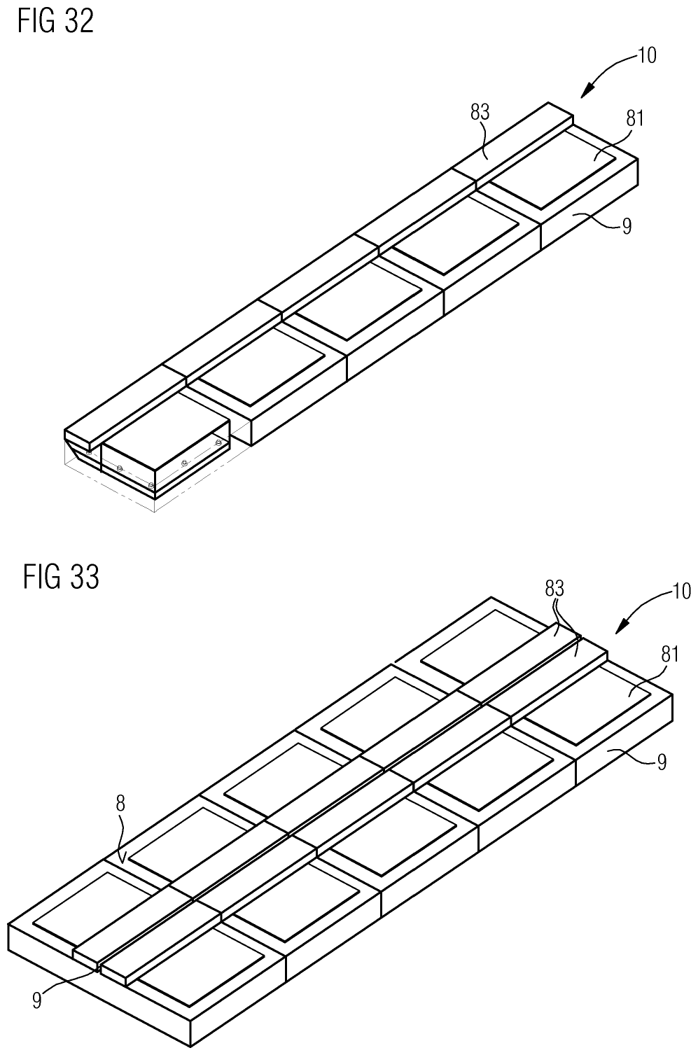

In the case of semiconductor component 10 in FIG. 31, the stripe with the phosphor 83 is not located centrally above the semiconductor chip 1, but off-center, for example at one edge. Thus an asymmetrical radiation characteristic can be obtained, also called Batwing characteristic. In all other respects the semiconductor component 10 of FIG. 31 corresponds to that of FIGS. 24 to 27, the explanations given for these figures apply accordingly to FIG. 31. Analogous to FIG. 30, several of the units according to FIG. 31 are concluded to form the semiconductor component 10 in FIG. 32.

FIG. 33 illustrates that two of the semiconductor components according to FIG. 10 may be rotated by 180° in relation to each other to form a single semiconductor component 10. In this way, a symmetrical batwing characteristic can be achieved, with intensity maxima, for example, at beam angles of at least 30° and/or at most 60°, relative to a perpendicular to the light emission side 8. Optionally, the two phosphors 83 are separated from each other by the potting 9 when viewed from above on the light emission side 8. Alternatively, the phosphors 83 may also be formed in one piece.

Unless otherwise indicated, the components shown in the figures follow each other directly in the order given. Layers not touching each other in the figures are spaced apart. If lines are drawn parallel to each other, the corresponding surfaces are aligned parallel to each other. Likewise, unless otherwise indicated, the relative positions of the drawn components to each other are correctly shown in the figures.

The invention described here is not limited by the description using the exemplary embodiments. Rather, the invention comprises each new feature as well as each combination of features, which in particular includes each combination of features in the claims, even if this feature or this combination itself is not explicitly specified in the claims or exemplary embodiments.

This patent application claims the priority of the German patent application 10 2018 118 355.0, the disclosure content of which is hereby incorporated by reference.

### REFERENCES

1 optoelectronic semiconductor chip
2 semiconductor layer sequence
20 back side
21 first region
22 second region
23 active zone
25 growth substrate
31 contact layer
32 through-connection
42 contact strip
52 strip mirror
61 metallic mirror layer
62 electrically insulation layer
63 support layer
64 adhesion promoting layer
65 transparent conductive layer
66 electrical insulation
67 contact metallization
71 first electrical contact surface
72 second electrical contact surface
8 light emission side
81 additional mirror
82 aperture
83 phosphor
84 clear potting
9 potting
10 optoelectronic semiconductor component
11 first electrical connection
12 second electrical connection
13 carrier
14 mounting side
15 front side
16 web
17 reflective coating

1. Optoelectronic semiconductor chip comprising: with a semiconductor layer sequence comprising an active zone for generating radiation between a first region and a second region;
several electrical through-connections via which the second region is electrically contacted,
several metallic contact strips via which the through-connections are electrically connected; and
a metallic contact layer via which the first region is electrically contacted; and
an electrical insulation layer between the contact strips and the contact layer;
wherein,
the semiconductor layer sequence comprises a back side formed by the first region,
the contact layer and the contact strips are located on the back side,
the through-connections extend from the contact strips through the first region and through the active zone into the second region, and
the contact strips are arranged at least predominantly between the back side and the contact layer,
the contact layer forms a first electrical contact surface in a central region, and
the contact layer and the first contact surface follow directly one another between adjacent contact strips in a direction away from the active zone in the first region of the semiconductor layer.

2. The optoelectronic semiconductor chip according to claim 1,
further comprising at least one strip mirror between the first region and the contact strips,
wherein the strip mirror is electrically insulating, and
wherein the contact layer in a central region extends without gaps and continuously over all contact strips.

3. The optoelectronic semiconductor chip according to claim 2,
wherein the contact strips, when viewed in cross-section, are completely enclosed by the strip mirror together with the insulation layer in regions between adjacent through-connections, and
wherein the strip mirror is a Bragg mirror.

4. The optoelectronic semiconductor chip according to claim 1,
wherein the contact strips are free of the contact layer only in an edge region of the semiconductor chip, when viewed in plan view, so that at least one second electrical contact surface is formed in the edge region of the contact strips.

5. The optoelectronic semiconductor chip according to claim 4,
wherein the contact strips are controllable electrically independently of one another individually or in groups, so that at least one separate second contact surface is provided for each contact strip or for each group.

6. The optoelectronic semiconductor chip according to claim 4,
wherein the contact strips are electrically short-circuited with each other, and wherein only one or only two second contact surfaces are provided for all contact strips together.

7. The optoelectronic semiconductor chip according to claim 4,
wherein the second contact surfaces are completely covered by the second region of the semiconductor layer sequence.

8. The optoelectronic semiconductor chip according to claim 1,
wherein the contact layer comprises an adhesion promoting layer, a metallic mirror layer and a metallic support layer which directly follow each other in the order given in the direction away from the semiconductor layer sequence,
wherein the adhesion promoting layer and/or the mirror layer is located directly on the insulation layer.

9. The optoelectronic semiconductor chip according to claim 1,
wherein a cross-sectional area of the contact strips and/or an areal density of the through-connections decreases towards a chip center, so that the active zone is configured to be less supplied with current in the chip center.

10. The optoelectronic semiconductor chip according to claim 1,
wherein an area percentage of the contact strips on the back side ranges from 10% to 25% and an area percentage of the through-connections on the back side ranges from 1% to 5%.

11. The optoelectronic semiconductor chip according to claim 1,
further comprising a growth substrate for the semiconductor layer sequence,
wherein the growth substrate is located at the second region and forms a mechanical supporting component of the semiconductor chip.

12. The optoelectronic semiconductor component comprising:
at least one semiconductor chip according to claim 1 on a front side; and
a carrier;
wherein:
the carrier comprises a first electrical connection for the first region and at least one second electrical connection for the second region,
the first connection extends through the carrier, and
a base surface of the first electrical connection is continuously at least 90% of a base surface of the first contact surface.

13. The optoelectronic semiconductor component according to claim 12,
wherein the second connection comprises a plurality of webs on the front side and is structured in the form of strips or a grid, and
wherein the first and the second connection on an mounting side opposite the front side are each formed by a continuous surface.

14. The optoelectronic semiconductor component according to claim 13,
wherein regions between the webs are filled with a reflective coating.

15. The optoelectronic semiconductor component according to claim 12,
wherein the carrier protrudes laterally beyond the semiconductor chip all around, and
wherein the second connection completely frames the semiconductor chip at the front side seen in plan view.

16. The optoelectronic semiconductor component according to claim 12,
wherein the semiconductor component is configured to operate the active zone with a current density of at least 4 A/mm²,
wherein the active zone comprises a base surface ranging from 0.5 mm² to 5 mm².

17. The optoelectronic semiconductor component according to claim 12,
further comprising a phosphor at least in a stripe over the semiconductor chip,
wherein the semiconductor chip is predominantly covered by an aperture so that light can only emerge from the semiconductor chip in the stripe.

18. An optoelectronic semiconductor chip comprising:
a semiconductor layer sequence comprising an active zone for generating radiation between a first region and a second region;
a plurality of electrical through-connections, via which the second region is electrically contacted;
a plurality of metallic contact strips, via which the through-connections are electrically connected;
a metallic contact layer, via which the first region is electrically contacted; and
an electrical insulation layer between the contact strips and the contact layer;
wherein:
the semiconductor layer sequence comprises a back side formed by the first region,
the contact layer and the contact strips are located on the back side,
the through-connections extend from the contact strips through the first region and through the active zone into the second region, and
the contact strips are arranged at least predominantly between the back side and the contact layer.

19. The optoelectronic semiconductor chip according to claim 18, further comprising at least one strip mirror between the first region and the contact strips, wherein the strip mirror is electrically insulating, and wherein the contact layer in the central region extends without gaps and continuously over all contact strips, and the contact layer in the central region forms a first electrical contact surface.

20. The optoelectronic semiconductor chip according to claim 18, wherein a cross-sectional area of the contact strips and/or an areal density of the through-connections decreases towards a chip center such that the active zone is configured to be less supplied with current in the chip center.
